(19) United States
(12) Patent Application Publication
(10) Pub. No.: US 2024/0371716 A1
(43) Pub. Date: Nov. 7, 2024

(54) CHIP PACKAGE STRUCTURE AND FABRICATION

(71) Applicant: YANGTZE MEMORY TECHNOLOGIES CO., LTD., Wuhan (CN)

(72) Inventors: Li TAO, Wuhan (CN); Baohua ZHANG, Wuhan (CN); Shanshan ZHAO, Wuhan (CN)

(21) Appl. No.: 18/364,262

(22) Filed: Aug. 2, 2023

(30) Foreign Application Priority Data
May 5, 2023 (CN) 2023104987647

(51) Int. Cl. H01L 23/31; H01L 21/56; H01L 23/427; H01L 23/433

(52) U.S. Cl. CPC H01L 23/3121; H01L 21/56; H01L 23/427; H01L 23/4334

(57) ABSTRACT

The present application provides a chip package structure and a fabrication method thereof, a memory and a memory system. The chip package structure includes a substrate, a chip on a side of the substrate, an energy storage material layer on a side of the chip opposite the substrate, and a package layer that includes a first portion covering the chip and a second portion covering the energy storage material layer. According to the present application, by disposing the energy storage material layer on a side of the chip, the energy storage material layer absorbs the heat generated by the chip, thereby improving the heat dissipation capability of the chip package structure for the chip.

### CROSS-REFERENCE TO RELATED APPLICATIONS

The present application claims priority to Chinese Patent Application No. 2023104987647, which was filed May 5, 2023, is titled “CHIP PACKAGE STRUCTURE AND FABRICATION,” and is hereby incorporated herein by reference in its entirety.

### TECHNICAL FIELD

The present application relates to the technical field of semiconductor package, and particularly to a chip package structure and a fabrication method thereof, a memory, and a memory system.

### BACKGROUND

With the improvement of performance of chip products, the power consumption of the chip products increases, such that the chip products generate a large amount of heat during usage. Therefore, the heat of the chip products needs to be dissipated timely.

Thus, there is an urgent need for a chip package structure and a fabrication method thereof, a memory and a memory system to solve the above technical.

### SUMMARY

In some examples, the present application provides a chip package structure that can dissipate heat of the chip products timely, and a fabrication method thereof, a memory and a memory system.

The present application provides a fabrication method of a chip package structure, which comprises: disposing a chip on a side of a substrate; disposing an energy storage material layer on a side of the chip opposite the substrate; and forming a package layer on a same side of the substrate as the chip, wherein the package layer covers the chip and the energy storage material layer.

In some examples of the present application, an orthographic projection of the chip on the substrate is within an orthographic projection of the energy storage material layer on the substrate.

In some examples of the present application, the chip package structure further comprises a first heat conduction support frame connected between the chip and the energy storage material layer; and before disposing the energy storage material layer on the side of the chip opposite the substrate, the fabrication method further comprises: disposing the first heat conduction support frame on the side of the chip opposite the substrate.

In some examples of the present application, disposing the energy storage material layer on the side of the chip opposite the substrate comprises: providing an energy storage material in liquid state; and cooling and solidifying the energy storage material in liquid state, to form the energy storage material layer on a side of the first heat conduction support frame opposite the chip.

In some examples of the present application, the energy storage material layer comprises a phase transition energy storage material and a heat conduction material; and providing the energy storage material in liquid state comprises: providing the phase transition energy storage material in liquid state; and mixing the heat conduction material into the phase transition energy storage material in liquid state, to form the energy storage material in liquid state.

In some examples of the present application, a mass fraction of the heat conduction material in the energy storage material layer is greater than or equal to 3%, and the mass fraction of the heat conduction material in the energy storage material layer is less than or equal to 8%.

In some examples of the present application, a phase transition temperature of the phase transition energy storage material is 28° C. to 44° C.; or an energy storage value of the phase transition energy storage material is 230 KJ/Kg to 250 KJ/Kg.

In some examples of the present application, the phase transition energy storage material is selected from straight-chain alkanes with 18 to 22 carbon atoms.

In some examples of the present application, the heat conduction material is selected from metal oxide powder or silicon dioxide powder.

The present application further provides a fabrication method of a chip package structure, which comprises: disposing a chip on a side of a substrate; forming a pre-package layer on a side of the chip opposite the substrate, wherein the pre-package layer covers the chip; forming a groove on a side of the pre-package layer opposite the substrate to form a first portion of a package layer; and filling an energy storage material within the groove to form an energy storage material layer, wherein the energy storage material layer comprises a phase transition energy storage material.

In some examples of the present application, an orthographic projection of the chip on the substrate is within an orthographic projection of the groove on the substrate.

In some examples of the present application, the package layer further comprises a second portion covering the energy storage material layer, and the second portion covering the energy storage material layer comprises a second heat conduction support frame, wherein the second heat conduction support frame comprises a support sub-portion and a cover plate sub-portion, the support sub-portion extends into the energy storage material layer, and the cover plate sub-portion is connected to an end of the support sub-portion opposite the chip and covers at least part of the energy storage material layer.

In some examples of the present application, filling the energy storage material within the groove to form the energy storage material layer comprises: providing an energy storage material in liquid state; filling the energy storage material in liquid state within the groove; disposing the second heat conduction support frame in the energy storage material in liquid state located within the groove to fully fill the groove; and cooling and solidifying the energy storage material within the groove to form the energy storage material layer.

In some examples of the present application, the energy storage material layer comprises a phase transition energy storage material and a heat conduction material; and providing the energy storage material in liquid state comprises: providing the phase transition energy storage material in liquid state; and mixing the heat conduction material into the phase transition energy storage material in liquid state, to form the energy storage material in liquid state.

In some examples of the present application, a mass fraction of the heat conduction material in the energy storage material layer is greater than or equal to 3%, and the mass fraction of the heat conduction material in the energy storage material layer is less than or equal to 8%.

In some examples of the present application, a phase transition temperature of the phase transition energy storage material is 28° C. to 44° C.; or an energy storage value of the phase transition energy storage material is 230 KJ/Kg to 250 KJ/Kg.

In some examples of the present application, the phase transition energy storage material is selected from straight-chain alkanes with 18 to 22 carbon atoms.

In some examples of the present application, the heat conduction material is selected from metal oxide powder or silicon dioxide powder.

In some examples of the present application, filling the energy storage material within the groove to form the energy storage material layer comprises: providing an energy storage material in solid state; and filling the energy storage material in solid state within the groove to form the energy storage material layer.

In some examples of the present application, after the filling the energy storage material within the groove to form the energy storage material layer, the fabrication method further comprises: providing the second heat conduction support frame; and placing the support sub-portion of the second heat conduction support frame into the energy storage material layer to fully fill the groove.

In some examples of the present application, an end of the support sub-portion close to the chip is in contact with the bottom of the groove, and a side of the cover plate sub-portion opposite the support sub-portion is coplanar with a side of the package layer outside the groove opposite the chip.

In some examples of the present application, the chip package structure further comprises a sealant filled between the cover plate sub-portion and a sidewall of the groove; and after filling the energy storage material within the groove to form the energy storage material layer, the fabrication method further comprises: filling the sealant between the cover plate sub-portion and the sidewall of the groove.

The present application further provides a chip package structure, comprising: a substrate; a chip on a side of the substrate; an energy storage material layer on a side of the chip opposite the substrate; and a package layer comprising a first portion covering the chip and a second portion covering the energy storage material layer.

In some examples of the present application, an orthographic projection of the chip on the substrate is within an orthographic projection of the energy storage material layer on the substrate.

In some examples of the present application, an area ratio of the orthographic projection of the energy storage material layer on the substrate to the orthographic projection of the chip on the substrate is in a range of 1:1 to 1.5:1.

In some examples of the present application, a material of the first portion covering the chip is the same as a material of the second portion covering the energy storage material layer.

In some examples of the present application, the chip package structure further comprises a first heat conduction support frame connected between the chip and the energy storage material layer.

In some examples of the present application, the first portion covering the chip comprises a groove that is located on a side of the first portion covering the chip opposite the substrate, and the energy storage material layer is filled within the groove; the second portion covering the energy storage material layer comprises a second heat conduction support frame that comprises a support sub-portion and a cover plate sub-portion, wherein the support sub-portion extends into the energy storage material layer, and the cover plate sub-portion is connected to an end of the support sub-portion opposite the chip and covers at least part of the energy storage material layer.

In some examples of the present application, an end of the support sub-portion close to the chip is in contact with the bottom of the groove, and a side of the cover plate sub-portion opposite the support sub-portion is coplanar with a side of the package layer outside the groove opposite the chip.

In some examples of the present application, the material of the first portion covering the chip comprises epoxy resin, and the material of the second portion covering the energy storage material layer comprises a metal.

In some examples of the present application, the chip package structure further comprises a sealant filled between the cover plate sub-portion and a sidewall of the groove.

In some examples of the present application, the energy storage material layer comprises a phase transition energy storage material, wherein a phase transition temperature of the phase transition energy storage material is 28° C. to 44° C.; or an energy storage value of the phase transition energy storage material is 230 KJ/Kg to 250 KJ/Kg.

In some examples of the present application, the phase transition energy storage material is selected from straight-chain alkanes with 18 to 22 carbon atoms.

In some examples of the present application, the energy storage material layer further comprises a heat conduction material that is selected from metal oxide powder or silicon dioxide powder.

The present application further provides a memory comprising the chip package structure of any one of the above examples.

The present application further provides a memory system comprising a memory, and a controller coupled to the memory and configured to control the memory to store data, wherein the memory comprises the chip package structure of any one of the above examples.

According to the chip package structure and the fabrication method thereof, the memory and the memory system provided by the present application, the energy storage material layer is disposed on a side of the chip and the energy storage material layer timely absorbs the heat generated by the chip, thereby improving the heat dissipation capability of the chip package structure for the chip.

### BRIEF DESCRIPTION OF THE DRAWINGS

To illustrate the technical solutions of some examples of the present application more clearly, the drawings to be used in the description of examples are briefly introduced below. The drawings described below are only some examples of the present application. Those skilled in the art may also obtain other drawings according to these drawings without creative work.

FIG. 1 is a flow diagram of a fabrication method of a first chip package structure provided by examples of the present application.

FIGS. 2A to 2D are schematic structure diagrams corresponding to various processes in a fabrication method of a first chip package structure provided by examples of the present application.

FIG. 3 is a flow diagram of a fabrication method of a second chip package structure provided by examples of the present application.

FIGS. 4A to 4F are schematic structure diagrams corresponding to various processes in a fabrication method of a second chip package structure provided by examples of the present application.

FIG. 5 is a first schematic structure diagram of a chip package structure provided by examples of the present application.

FIG. 6 is a second schematic structure diagram of a chip package structure provided by examples of the present application,

FIG. 7 is a schematic result diagram of heating-up inhibition of a chip package structure provided by examples of the present application.

FIG. 8 is a schematic structure diagram of a memory system provided by examples of the present application.

FIG. 9 is a flow diagram of a fabrication method of a chip package structure provided by examples of the present application.

FIG. 10 is a flow diagram of a fabrication method of a chip package structure provided by examples of the present application.

FIG. 11 is a flow diagram of a fabrication method of a chip package structure provided by examples of the present application.

### DETAILED DESCRIPTION

The technical solutions of some examples of the present application are described below in conjunction with the drawings. The examples described are only part of, but not all of, the examples of the present application. All other examples obtained by those skilled in the art based on the examples in the present application without creative work shall fall in the scope of protection of the present application.

In the description of the present application, the terms “upper,” “lower,” etc. indicate orientations or position relationships that are based on the orientations or position relationships as shown in the drawings, are only intended to facilitate description of the present application and to simplify the description, instead of indicating or implying that the device or element indicated must have a specific orientation and be configured and operated in a specific orientation, and thus cannot be understood as limiting the present application. Furthermore, the terms “first” and “second” are only for the purpose of description, and cannot be construed as indicating or implying relative importance or implicitly indicating the number of indicated technical features. Thus, features defined by “first” and “second” may explicitly or implicitly include one or more of the features. In the description of the present application, “a plurality of” means two or more, unless otherwise defined.

The present application may repeat the reference numbers and/or reference letters in different implementations, and such repetitions are for the purposes of simplification and clarity, and do not indicate in themselves the relationships between various implementations and/or settings as discussed.

The present application includes examples that address the technical problem of dissipating heat generated during usage of a chip with increasing power consumption as the performance of the chip are improved, such as generated by the chip when the instantaneous power consumption of the chip is about 3 to 5 times the average power consumption. By disposing an energy storage material layer on a side of the chip in the chip package structure, the heat generated by the chip can be absorbed, thereby increasing heat dissipation of the chip.

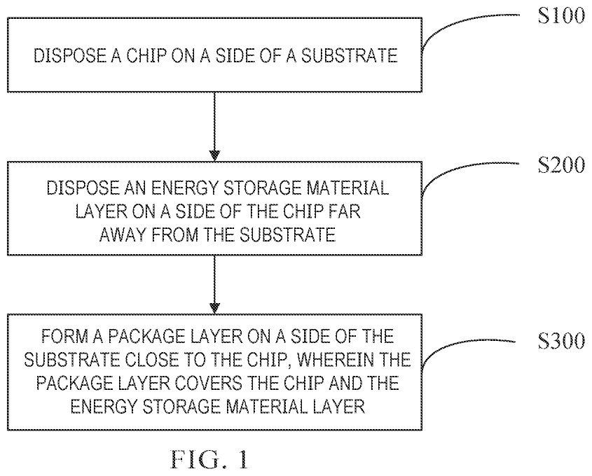

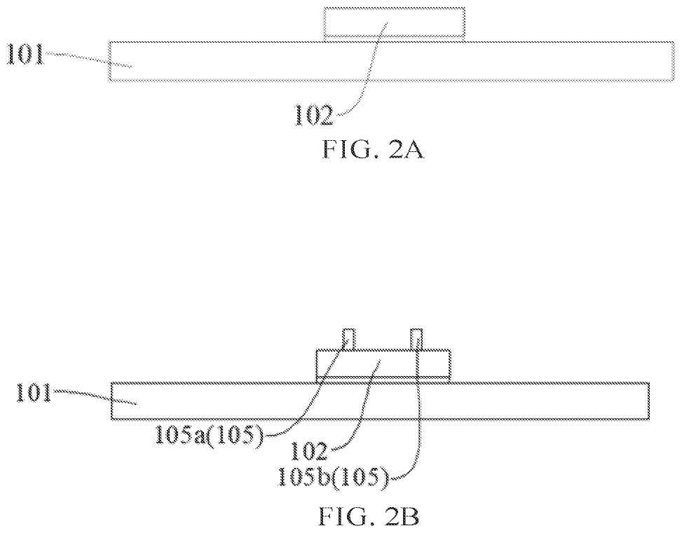

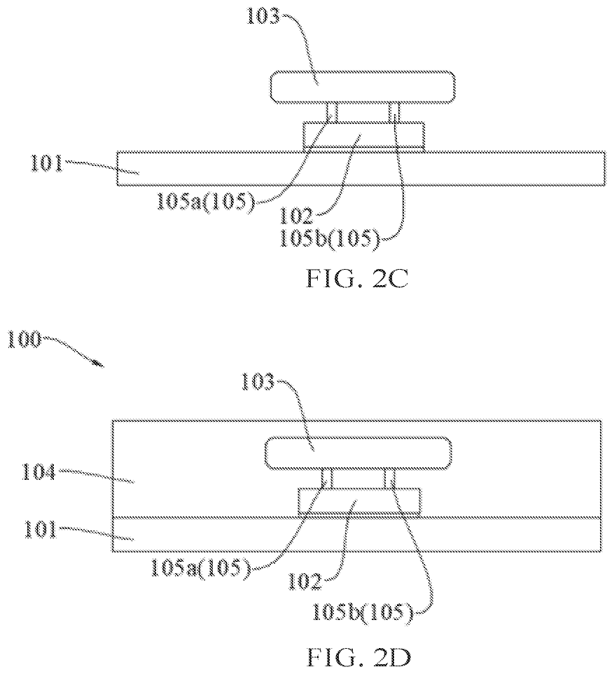

Referring to FIGS. 1, and 2A to 2D, some examples of the present application provide a fabrication method of a chip package structure 100, which comprises:

Operation S100: referring to FIGS. 1 and 2A, disposing a chip 102 on a side of a substrate 101.

In some examples of the present application, the substrate 101 may be either an ordinary carrier substrate, or a substrate with a circuit structure. When the substrate 101 is an ordinary carrier substrate, a lead frame to be externally connected with devices may be provided on the carrier substrate to be electrically connected with the chip 102.

In some examples of the present application, the chip 102 may comprise a controller chip, a memory chip, and the like. The memory chip may be a three-dimensional (3D) NAND chip.

The fabrication method further comprises operation S200: referring to FIGS. 1 and 2C, disposing an energy storage material layer 103 on a side of the chip 102 opposite the substrate 101.

In some examples of the present application, an orthographic projection of the chip 102 on the substrate 101 is within an orthographic projection of the energy storage material layer 103 on the substrate 101.

In some examples of the present application, a ratio of the area of the orthographic projection of the energy storage material layer 103 on the substrate 101 to the area of the orthographic projection of the chip 102 on the substrate 101 is in a range of 1:1 to 1.5:1, for example, 1.2:1, 1.3:1, 1.4:1, etc.

In some examples of the present application, the energy storage material layer 103 comprises a phase transition energy storage material. The phase transition energy storage material utilizes a transition process from the solid state to the liquid state to absorb a large amount of heat. As a result, the temperature rise is limited before the physical state transition is completed, thus slowing overall heating-up of the chip package structure 100 and inhibiting the heating-up of the chip 102 by absorbing the heat generated by the chip 102.

In some examples of the present application, a phase transition temperature of the phase transition energy storage material is 28° C. to 44° C., so as to absorb the heat generated by the chip 102 prior to overheating of the chip 102, inhibit instantaneous temperature increase of the chip 102, and avoid damaging the chip 102.

In some examples of the present application, an energy storage value of the phase transition energy storage material is 230 kilojoules (KJ) per kilogram (Kg) to 250 KJ/Kg, such that the phase transition energy storage material remains at its melting point for an increased time during the solid state to liquid state transition. This may slow down the overall heating-up of the chip package structure 100 and improve the heat dissipation capability of the chip package structure 100 for the chip 102 while inhibiting the instantaneous temperature increase of the chip 102.

In some examples of the present application, the phase transition energy storage material is selected from straight-chain alkanes with 18 to 22 carbon atoms, such as n-octadecane, n-nonadecane, n-eicosane, n-heneicosane, n-docosane and the like. If the phase transition energy storage material is selected from the straight-chain alkanes with 18 to 22 carbon atoms, when the phase transition energy storage material transitions from the solid state to the liquid state by absorbing the heat from the chip 102, a variation in a density of the phase transition energy storage material is less than or equal to 3%, and the fluidity of the phase transition energy storage material is not enhanced significantly, such that the phase transition energy storage material is not prone to flow away during usage due to repeated state variations, which may extend service life of the chip package structure 100. Meanwhile, when the phase transition energy storage material is selected from the straight-chain alkanes with 18 to 22 carbon atoms, the phase transition temperature of the phase transition energy storage material is 28° C. to 44° C., and the energy storage value of the phase transition energy storage material is 230 KJ/Kg to 250 KJ/Kg, which may absorb the heat generated by the chip 102 timely prior to overheating of the chip 102. Moreover, the phase transition energy storage material remains at its melting point for an increased time when the transition from the solid state to the liquid state occurs, which may improve the heat dissipation capability of the chip package structure 100 for the chip 102.

In some examples of the present application, the energy storage material layer 103 further comprises a heat conduction material that is dispersed in the phase transition energy storage material. This may increase transfer of heat from the chip 102 to the phase transition energy storage material, such that the energy storage material layer 103 absorbs the heat generated by the chip 102 during working, which may improve the heat dissipation capability of the chip package structure 100 for the chip 102.

In some examples of the present application, the heat conduction material is selected from metal oxide powder or silicon dioxide powder. The metal oxide powder may be powder of a metal oxide with good heat conductivity, such as aluminum oxide, etc.

In some examples of the present application, a mass fraction of the heat conduction material in the energy storage material layer 103 is greater than or equal to 3%, and the mass fraction of the heat conduction material in the energy storage material layer 103 is less than or equal to 8%. For example, the mass fraction of the heat conduction material in the energy storage material layer 103 may be 4%, 5%, 6%, 7%, etc.

In some examples of the present application, the chip package structure 100 further comprises a first heat conduction support frame 105 connected between the chip 102 and the energy storage material layer 103, which may increase transfer of heat from the chip 102 to the energy storage material layer 103, such that the energy storage material layer 103 absorbs the heat generated by the chip 102 during working.

When the chip package structure 100 further comprises the first heat conduction support frame 105 connected between the chip 102 and the energy storage material layer 103, prior to operation S200, the fabrication method further comprises, referring to FIG. 2B, disposing the first heat conduction support frame 105 on a side of the chip 102 opposite the substrate 101.

In some examples of the present application, the first heat conduction support frame 105 comprises at least a first connection sub-portion, wherein an end of the first connection sub-portion close to the chip 102 is in direct contact with the chip 102; or the end of the first connection sub-portion close to the chip 102 is disposed as being adhered to the chip 102.

When the first heat conduction support frame 105 has a plurality of first connection sub-portions, the plurality of first connection sub-portions are arranged as being spaced apart along a direction parallel to the substrate 101, and extending directions of the plurality of first connection sub-portions may be parallel to each other. For example, the first heat conduction support frame 105 may have two first connection sub-portions (as shown by 105a and 105b in FIGS. 2B to 2D), wherein the two first connection sub-portions are located on a side of the chip 102 opposite the substrate 101 and are arranged as being spaced apart, and the extending directions of the two first connection sub-portions are parallel to each other.

In some examples, an end of each of the first connection sub-portions close to the energy storage material layer 103 is in direct contact with the energy storage material layer 103; or the end of each of the first connection sub-portions close to the energy storage material layer 103 is disposed as being adhered to the energy storage material layer 103. In some examples, in a direction from the chip 102 to the energy storage material layer 103, the first heat conduction support frame 105 further comprises a second connection sub-portion (not shown) on a side of the first connection sub-portions close to the energy storage material layer 103, the side of the first connection sub-portions close to the energy storage material layer 103 is connected with the second connection sub-portion, and the second connection sub-portion is in direct contact with the energy storage material layer 103.

Orthographic projections of the first connection sub-portions on the substrate 101 are within an orthographic projection of the second connection sub-portion on the substrate 101, e.g., the area of the orthographic projection of the second connection sub-portion on the substrate 101 is greater than a sum of areas of the orthographic projections of the first connection sub-portions on the substrate 101. By disposing the second connection sub-portion, the contact area between the first heat conduction support frame 105 and the energy storage material layer 103 is increased, which may cause the first heat conduction support frame 105 to transfer the heat generated by the chip 102 to the energy storage material layer 103, thereby improving the heat dissipation capability of the chip package structure 100 for the chip 102.

In some examples of the present application, in the direction from the chip 102 to the energy storage material layer 103, a side of the energy storage material layer 103 close to the chip 102 is entirely in contact with the second connection sub-portion, providing full contact between the energy storage material layer 103 and the first heat conduction support frame 105. The first heat conduction support frame 105 transfers the heat generated by the chip 102 to the energy storage material layer 103, thereby improving the heat dissipation capability of the chip package structure 100 for the chip 102.

In some examples of the present application, the first connection sub-portions and the second connection sub-portion may be disposed integrally.

In some examples of the present application, the material of the first heat conduction support frame 105 is selected from a metal, a metal oxide or silicon dioxide, wherein the metal may be selected from metals such as copper, aluminum and the like, or an alloy including the above-mentioned metals; and the metal oxide may be selected from metal oxides with a heat conduction property, such as aluminum oxide, etc.

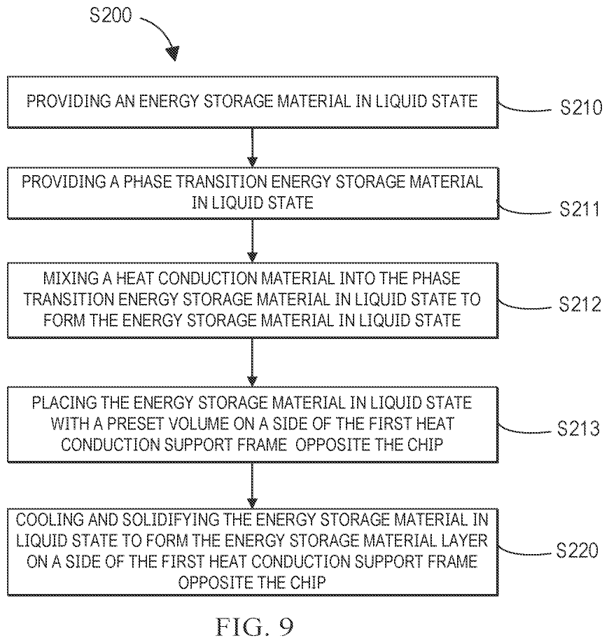

As shown in FIG. 9, in some examples of the present application, when the chip package structure 100 further comprises the first heat conduction support frame 105 connected between the chip 102 and the energy storage material layer 103, operation S200 comprises: providing an energy storage material in liquid state in operation S210; and in operation S220, cooling and solidifying the energy storage material in liquid state, so as to form the energy storage material layer 103 on a side of the first heat conduction support frame 105 opposite the chip 102.

As further shown in FIG. 9, in some examples, operation S210 comprises: providing the phase transition energy storage material in liquid state in operation S211; in operation S212, mixing a heat conduction material into the phase transition energy storage material in liquid state, to form the energy storage material in liquid state; and in operation S213, placing the energy storage material in liquid state with a preset volume on a side of the first heat conduction support frame 105 opposite the chip 102.

In some examples of the present application, operation S211 comprises: providing a first mold in operation S211a (not shown), wherein the phase transition energy storage material is heated and molten in the first mold to form the phase transition energy storage material in liquid state with the preset volume.

In some examples of the present application, operation S212 comprises: in operation S212a (not shown), mixing a heat conduction material into the phase transition energy storage material in liquid state in the first mold, to form the energy storage material in liquid state.

In some examples of the present application, operation S220 comprises: in operation S221 (not shown), cooling and solidifying the energy storage material in liquid state with the preset volume, so as to form the energy storage material layer 103 on a side of the first heat conduction support frame 105 opposite the chip 102.

In some examples of the present application, when the chip package structure 100 further comprises the first heat conduction support frame 105 connected between the chip 102 and the energy storage material layer 103, operation S200 comprises: in operation S230 (not shown), providing the energy storage material in solid state; and in operation S240 (not shown), disposing the energy storage material in solid state on a side of the first heat conduction support frame 105 opposite the chip 102 to form the energy storage material layer 103.

In some examples of the present application, operation S230 comprises: in operation S231 (not shown), providing the phase transition energy storage material in liquid state; in operation S232 (not shown), mixing a heat conduction material into the phase transition energy storage material in liquid state, to form the energy storage material in liquid state; and in operation S233 (not shown), cooling and solidifying the energy storage material in liquid state to form the energy storage material in solid state.

In some examples of the present application, operation S231 comprises: in operation S231a (not shown), providing a second mold, wherein the phase transition energy storage material is heated and molten in the second mold to form the phase transition energy storage material in liquid state with the preset volume.

In some examples of the present application, operation S232 comprises: in operation S232a (not shown), mixing a heat conduction material into the phase transition energy storage material in liquid state in the second mold to form the energy storage material in liquid state.

In some examples of the present application, operation S233 comprises: in operation S233a (not shown), cooling and solidifying the energy storage material in liquid state in the second mold.

In some examples of the present application, operation S240 comprises: in operation S241 (not shown), transferring the energy storage material in solid state from the second mold and placing the energy storage material in solid state on a side of the first heat conduction support frame 105 opposite the chip 102 to form the energy storage material layer 103.

The fabrication method further comprises operation S300: referring to FIGS. 1 and 2D, forming a package layer 104 on a same side of the substrate 101 as the chip 102, wherein the package layer 104 covers the chip 102 and the energy storage material layer 103.

In some examples of the present application, the material of package layer 104 may comprise a plastic package material that may comprise an epoxy resin plastic package material.

In some examples of the present application, the plastic package material of the package layer 104 covers the chip 102 and the energy storage material layer 103. For example, the chip 102 and the energy storage material layer 103 are entirely cladded within the plastic package material of the package layer 104.

According to the fabrication method of the chip package structure 100 provided by the present application, the energy storage material layer 103 is formed on a side of the chip 102 opposite the substrate 101. The plastic package material of the package layer 104 covers the chip 102 and the energy storage material layer 103 such that while the chip package structure 100 is packaged, the energy storage material layer 103 absorbs the heat generated by the chip 102, thereby improving the heat dissipation capability of the chip package structure 100 for the chip 102.

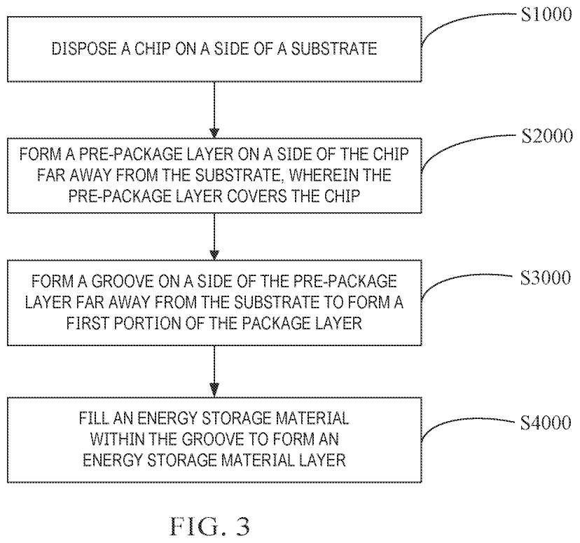

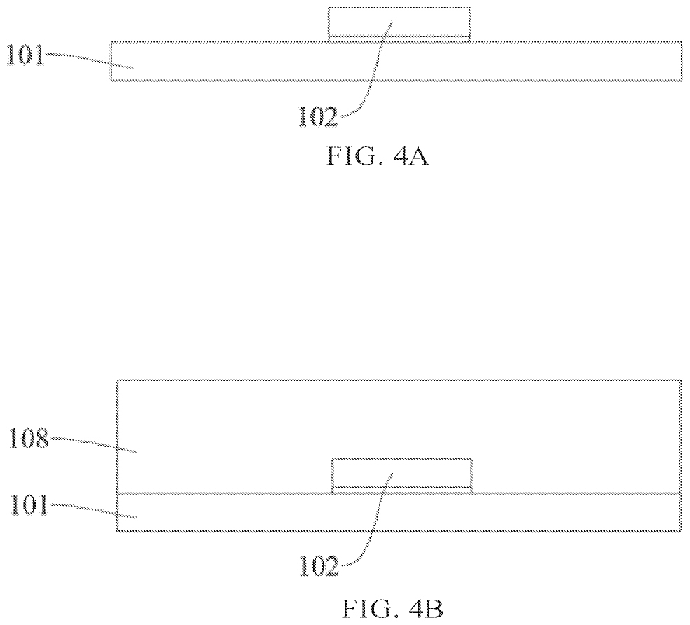

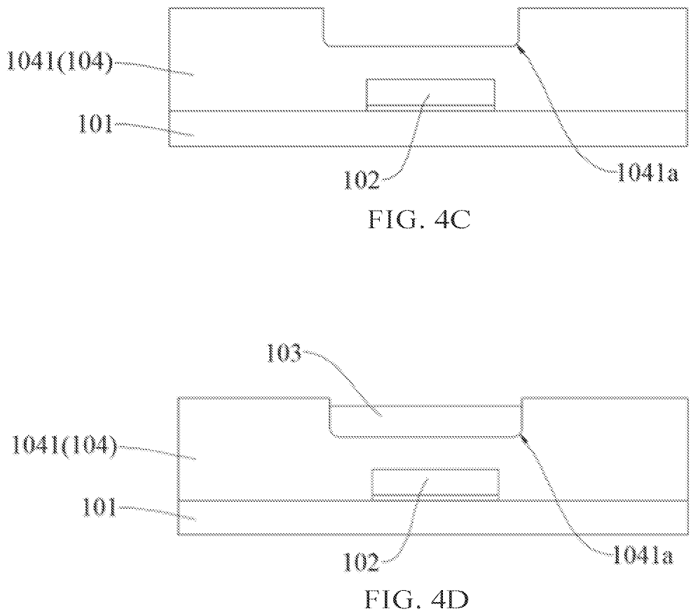

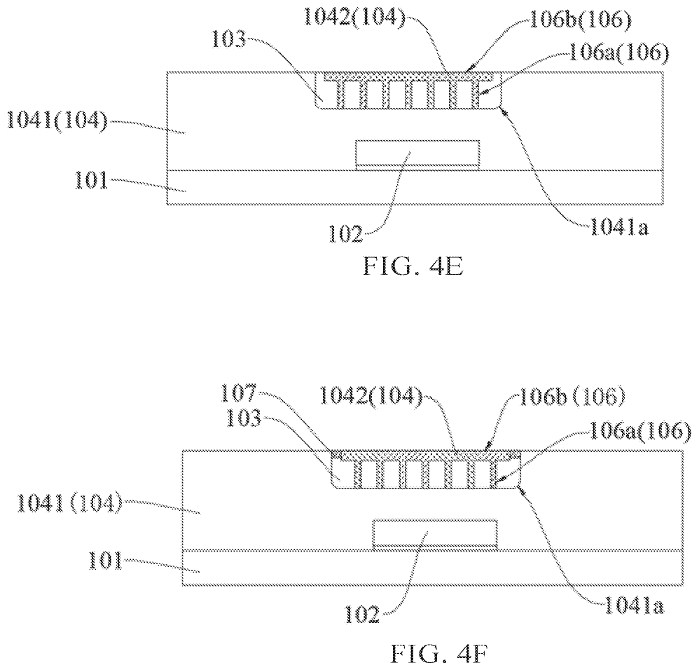

Referring to FIGS. 3, and 4A to 4F, some examples of the present application further provide a fabrication method of a chip package structure 100, which comprises:

Operation S1000: referring to FIGS. 3 and 4A, disposing a chip 102 on a side of a substrate 101.

In some examples of the present application, the substrate 101 may be either an ordinary carrier substrate, or a substrate with a circuit structure. When the substrate 101 is an ordinary carrier substrate, a lead frame to be externally connected with devices may be provided on the carrier substrate to be electrically connected with the chip 102.

In some examples of the present application, the chip 102 may comprise a controller chip, a memory chip, and the like. The memory chip may be a 3D NAND chip.

The fabrication method further comprises operation S2000: referring to FIGS. 3 and 4B, forming a pre-package layer 108 on a side of the chip 102 opposite the substrate 101, wherein the pre-package layer 108 covers the chip 102.

In some examples of the present application, the material of the pre-package layer 108 may comprise a plastic package material that may comprise an epoxy resin plastic package material.

In some examples of the present application, the plastic package material of the pre-package layer 108 covers the chip 102, e.g., the chip 102 is entirely cladded within the plastic package material of the package layer 104.

The fabrication method further comprises operation S3000: referring to FIGS. 3 and 4C, forming a groove 1041a on a side of the pre-package layer 108 opposite the substrate 101 to form a first portion 1041 of the package layer 104.

In some examples of the present application, an orthographic projection of the chip 102 on the substrate 101 is within an orthographic projection of the groove 1041a on the substrate 101.

In some examples of the present application, a ratio of the area of the orthographic projection of the groove 1041a on the substrate 101 to the area of the orthographic projection of the chip 102 on the substrate 101 is in a range of 1:1 to 1.5:1, for example, 1.2:1, 1.3:1, 1.4:1, etc.

In some examples of the present application, in a direction from the substrate 101 to the groove 1041a, a spacing between a side of the groove 1041a close to the chip 102 and the chip 102 is greater than zero. For example, the chip 102 is entirely cladded within the first portion 1041 of the package layer 104, which is favorable to effective packaging of the chip package structure 100 for the chip 102.

The fabrication method further comprises operation S4000: referring to FIGS. 3, 4D and 4E, filling an energy storage material within the groove 1041a to form an energy storage material layer 103.

The energy storage material layer 103 comprises a phase transition energy storage material. The phase transition energy storage material utilizes a transition process from the solid state to the liquid state to absorb heat. As a result, the temperature rise is limited before the physical state transition is completed, thus slowing overall heating-up of the chip package structure 100 and inhibiting the heating-up of the chip 102 by absorbing the heat generated by the chip 102.

In some examples of the present application, a phase transition temperature of the phase transition energy storage material is 28° C. to 44° C., so as to absorb the heat generated by the chip 102 prior to overheating of the chip 102, inhibit instantaneous temperature increase of the chip 102, and avoid damaging the chip 102.

In some examples of the present application, an energy storage value of the phase transition energy storage material is 230 KJ/Kg to 250 KJ/Kg, such that the phase transition energy storage material remains at its melting point for an increased time during the solid state to liquid state transition. This may slow down the overall heating-up of the chip package structure 100 and improve the heat dissipation capability of the chip package structure 100 for the chip 102 while inhibiting the instantaneous temperature increase of the chip 102.

In some examples of the present application, the phase transition energy storage material is selected from straight-chain alkanes with 18 to 22 carbon atoms, such as n-octadecane, n-nonadecane, n-eicosane, n-heneicosane, n-docosane and the like. If the phase transition energy storage material is selected from the straight-chain alkanes with 18 to 22 carbon atoms, when the phase transition energy storage material transitions from the solid state to the liquid state by absorbing the heat from the chip 102, a variation in a density of the phase transition energy storage material is less than or equal to 3%, and the fluidity of the phase transition energy storage material is not enhanced significantly, such that the phase transition energy storage material is not prone to flow away during usage due to repeated state variations, which may extend service life of the chip package structure 100. Meanwhile, when the phase transition energy storage material is selected from the straight-chain alkanes with 18 to 22 carbon atoms, the phase transition temperature of the phase transition energy storage material is 28° C. to 44° C., and the energy storage value of the phase transition energy storage material is 230 KJ/Kg to 250 KJ/Kg, which may absorb the heat generated by the chip 102 timely prior to overheating of the chip 102. Moreover, the phase transition energy storage material remains at its melting point for an increased time when the transition from the solid state to the liquid state occurs, which may improve the heat dissipation capability of the chip package structure 100 for the chip 102.

In some examples of the present application, the energy storage material layer 103 further comprises a heat conduction material that is dispersed in the phase transition energy storage material. This may increase transfer of the heat from the chip 102 to the phase transition energy storage material, such that the energy storage material layer 103 absorbs the heat generated by the chip 102 during working, which may improve the heat dissipation capability of the chip package structure 100 for the chip 102.

In some examples of the present application, the heat conduction material is selected from metal oxide powder or silicon dioxide powder. The metal oxide powder may be powder of a metal oxide with good heat conductivity, such as aluminum oxide, etc.

In some examples of the present application, a mass fraction of the heat conduction material in the energy storage material layer 103 is greater than or equal to 3%, and the mass fraction of the heat conduction material in the energy storage material layer 103 is less than or equal to 8%. For example, the mass fraction of the heat conduction material in the energy storage material layer 103 may be 4%, 5%, 6%, 7%, etc.

In some examples of the present application, the package layer 104 further comprises a second portion 1042 covering the energy storage material layer 103, wherein the second portion 1042 covering the energy storage material layer 103 comprises a second heat conduction support frame 106.

The second heat conduction support frame 106 comprises a support sub-portion 106a and a cover plate sub-portion 106b, wherein the support sub-portion 106a extends into the energy storage material layer 103, and the cover plate sub-portion 106b is connected to an end of the support sub-portion 106a opposite the chip 102 and covers at least part of the energy storage material layer 103.

In some examples of the present application, an end of the support sub-portion 106a close to the chip 102 is in contact with the bottom of the groove 1041a, and a side of the cover plate sub-portion 106b opposite the support sub-portion 106a is coplanar with a side of the package layer 104 outside the groove 1041a opposite the chip 102.

In some examples of the present application, the second heat conduction support frame 106 comprises one or more support sub-portions 106a. When the second heat conduction support frame 106 comprises a plurality of support sub-portions 106a, the plurality of support sub-portions 106a are arranged spaced apart in a direction parallel to the substrate 101, and extending directions of the plurality of support sub-portions 106a may be parallel to each other. In an example, the second heat conduction support frame 106 comprises the plurality of support sub-portions 106a, which increases the contact area between the second heat conduction support frame 106 and the energy storage material layer 103. An end of each of the support sub-portions 106a close to the chip 102 is in contact with the bottom of the groove 1041a. After the heat generated by the chip 102 is transferred to the groove 1041a, the heat from the chip 102 is transferred to the energy storage material layer 103 through the support sub-portions 106a in contact with the groove 1041a, thereby improving the heat dissipation capability of the chip package structure 100 for the chip 102.

In some examples of the present application, the support sub-portions 106a and the cover plate sub-portion 106b are disposed integrally.

In some examples of the present application, the material of the second heat conduction support frame 106 is selected from a metal or silicon dioxide, wherein the metal may be selected from metals such as copper, aluminum and the like, or an alloy including the above-mentioned metals.

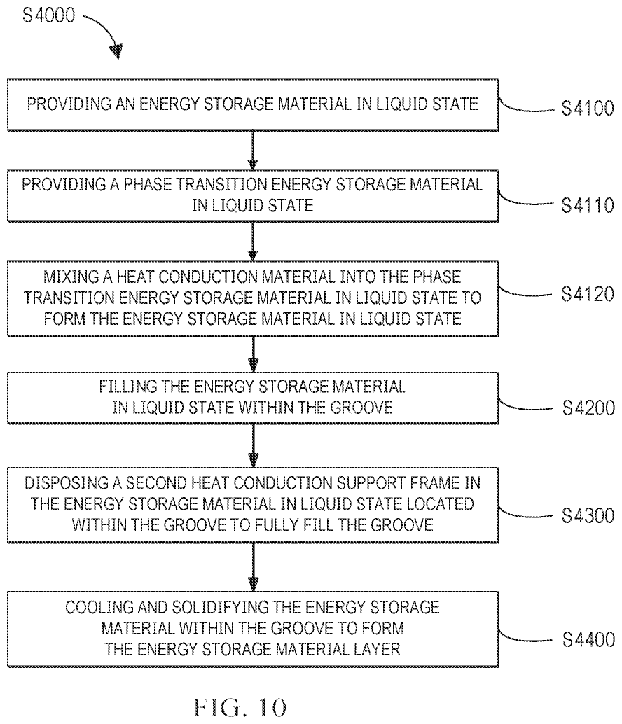

As shown in FIG. 10, in some examples of the present application, when the second portion 1042 covering the energy storage material layer 103 comprises the second heat conduction support frame 106, operation S4000 comprises: in operation S4100, providing an energy storage material in liquid state; and in operation S4200, filling the energy storage material in liquid state within the groove 1041a. In operation S4300, the fabrication method includes disposing the second heat conduction support frame 106 in the energy storage material in liquid state located within the groove 1041a to fully fill the groove 1041a; referring to FIG. 4E, in some examples of the present application. In operation S4300, the second heat conduction support frame 106 is inserted into the energy storage material in liquid state, and part of the energy storage material overflows to a gap between the cover plate sub-portion 106b and a sidewall of the groove 1041a. Part of the energy storage material is filled in the gap between the cover plate sub-portion 106b and the sidewall of the groove 1041a, so that the energy storage material and the second heat conduction support frame 106 fully fill the groove 1041a. In operation S4400, the fabrication method includes cooling and solidifying the energy storage material within the groove 1041a to form the energy storage material layer 103.

As further shown in FIG. 10, in some examples of the present application, operation S4100 comprises: in operation S4110, providing the phase transition energy storage material in liquid state; and in operation S4120, mixing a heat conduction material into the phase transition energy storage material in liquid state to form the energy storage material in liquid state.

In some examples of the present application, operation S4110 comprises: in operation S4111 (not shown), providing a third mold, wherein the phase transition energy storage material is heated and molten in the third mold to form the phase transition energy storage material in liquid state with a preset volume.

In some examples of the present application, operation S4120 comprises: in operation S4121 (not shown), mixing a heat conduction material into the phase transition energy storage material in liquid state in the third mold to form the energy storage material in liquid state.

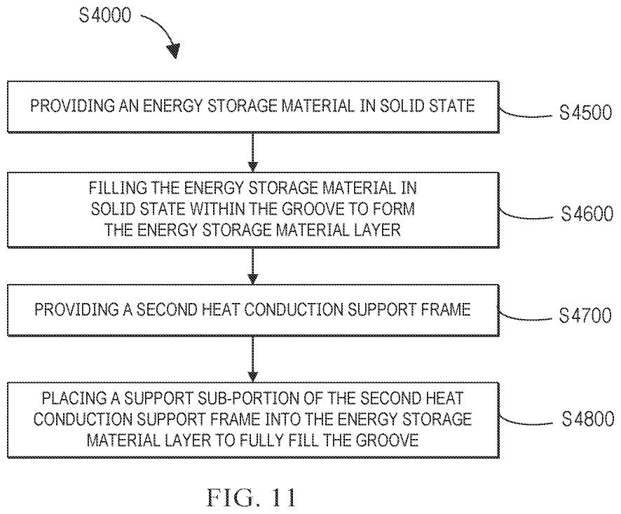

As shown in FIG. 11, in some examples of the present application, operation S4000 comprises: in operation S4500, providing the energy storage material in solid state; and in operation S4600, filling the energy storage material in solid state within the groove 1041a to form the energy storage material layer 103. In operation S4700, the fabrication method includes providing the second heat conduction support frame 106; and in operation S4800, placing the support sub-portions 106a of the second heat conduction support frame 106 into the energy storage material layer 103 to fully fill the groove 1041a.

In some examples of the present application, in operation S4800, the second heat conduction support frame 106 is inserted into the energy storage material in solid state, and part of the energy storage material overflows to a gap between the cover plate sub-portion 106b and the sidewall of the groove 1041a. Part of the energy storage material is filled in the gap between the cover plate sub-portion 106b and the sidewall of the groove 1041a, so that the energy storage material and the second heat conduction support frame 106 fully fill the groove 1041a.

In some examples of the present application, operation S4500 comprises: in operation S4510 (not shown), providing the phase transition energy storage material in liquid state; in operation S4520 (not shown), mixing a heat conduction material into the phase transition energy storage material in liquid state, to form the energy storage material in liquid state; and in operation S4530 (not shown), cooling and solidifying the energy storage material in liquid state to form the energy storage material in solid state.

In some examples of the present application, operation S4510 comprises: in operation S4511 (not shown), providing a fourth mold, wherein the phase transition energy storage material is heated and molten in the fourth mold to form the phase transition energy storage material in liquid state with a preset volume.

In some examples of the present application, operation S4520 comprises: in operation S4521 (not shown), mixing a heat conduction material into the phase transition energy storage material in liquid state in the fourth mold to form the energy storage material in liquid state.

In some examples of the present application, operation S4530 comprises: in operation S4531 (not shown), cooling and solidifying the energy storage material in liquid state in the fourth mold.

In some examples of the present application, operation S4600 comprises: in operation S4610 (not shown), transferring the energy storage material in solid state from the fourth mold and filling the energy storage material in solid state within the groove 1041a to form the energy storage material layer 103.

In some examples of the present application, the chip package structure 100 further comprises a sealant 107 filled between the cover plate sub-portion 106b and the sidewall of the groove 1041a.

There is a gap between the cover plate sub-portion 106b and the sidewall of the groove 1041a, and the sealant 107 is filled between the cover plate sub-portion 106b and the sidewall of the groove 1041a to fill the gap, thus enhancing the effect of packaging of the chip package structure 100.

In some examples of the present application, when the chip package structure 100 further comprises the sealant 107 filled between the cover plate sub-portion 106b and the sidewall of the groove 1041a, the fabrication method further comprises: referring to FIG. 4F, filling the sealant 107 between the cover plate sub-portion 106b and the sidewall of the groove 1041a.

According to the fabrication method of another chip package structure 100 provided by the present application, the energy storage material layer 103 is formed within the groove 1041a of the first portion 1041 of the package layer 104 on a side of the chip 102 opposite the substrate 101. The second portion 1042 of the package layer 104 covers at least part of the energy storage material layer 103, and the energy storage material layer 103 timely absorbs the heat generated by the chip 102, thereby improving the heat dissipation capability of the chip package structure 100 for the chip 102.

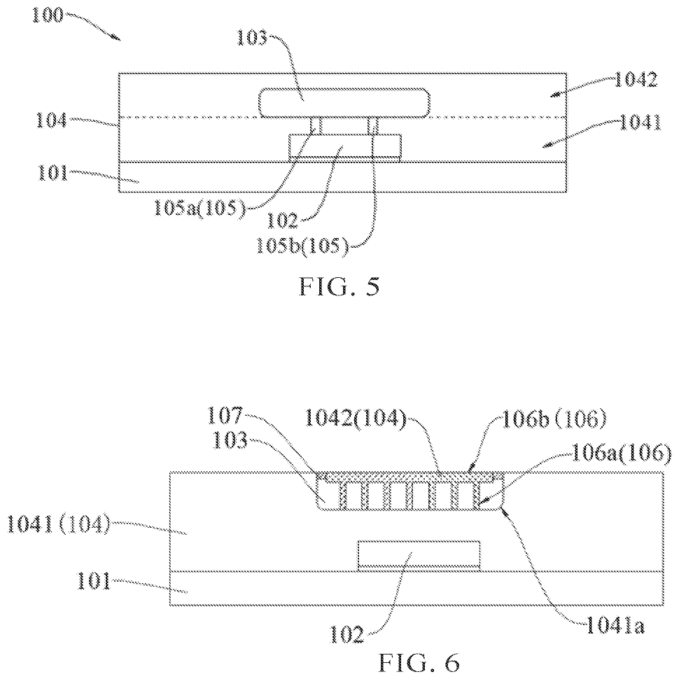

Referring to FIGS. 5 and 6, some examples of the present application provide a chip package structure 100, comprising: a substrate 101; a chip 102 on a side of the substrate 101; an energy storage material layer 103 on a side of the chip 102 opposite the substrate 101; and a package layer 104 that comprises a first portion 1041 covering the chip 102 and a second portion 1042 covering the energy storage material layer 103.

In some examples of the present application, an orthographic projection of the chip 102 on the substrate 101 is within an orthographic projection of the energy storage material layer 103 on the substrate 101.

In an example, an area ratio of the orthographic projection of the energy storage material layer 103 on the substrate 101 to the orthographic projection of the chip 102 on the substrate 101 is in a range of 1:1 to 1.5:1, for example, 1:1.2, 1:1.3, 1:1.41.2:1, 1.3:1, 1.4:1, etc.

In some examples of the present application, the energy storage material layer 103 comprises a phase transition energy storage material. The phase transition energy storage material utilizes a transition process from the solid state to the liquid state to absorb heat. As a result, the temperature rise is limited before the physical state transition is completed, thus slowing overall heating-up of the chip package structure 100 and inhibiting the heating-up of the chip 102 by absorbing the heat generated by the chip 102.

In some examples of the present application, a phase transition temperature of the phase transition energy storage material is 28° C. to 44° C., so as to absorb the heat generated by the chip 102 prior to overheating of the chip 102, inhibit instantaneous temperature increase of the chip 102, and avoid damaging the chip 102.

In some examples of the present application, an energy storage value of the phase transition energy storage material is 230 KJ/Kg to 250 KJ/Kg, such that the phase transition energy storage material remains at its melting point for an increased time during the solid state to liquid state transition. This may slow down the overall heating-up of the chip package structure 100 and improve the heat dissipation capability of the chip package structure 100 for the chip 102 while inhibiting the instantaneous temperature increase of the chip 102.

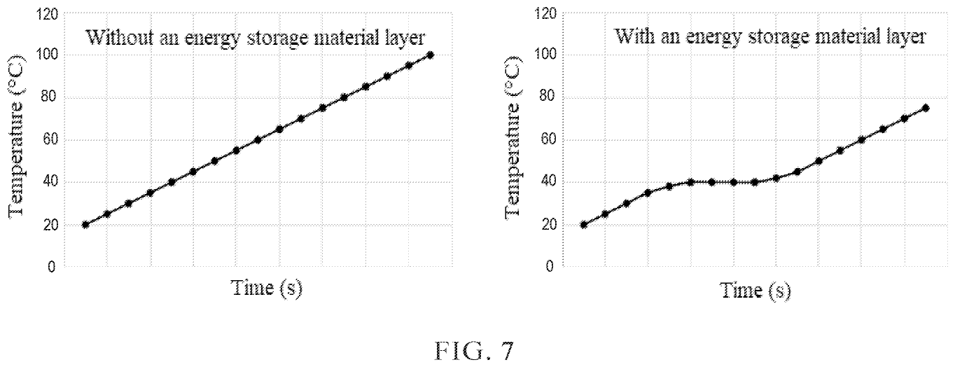

In some examples of the present application, the phase transition energy storage material is selected from straight-chain alkanes with 18 to 22 carbon atoms, such as n-octadecane, n-nonadecane, n-eicosane, n-heneicosane, n-docosane and the like. If the phase transition energy storage material is selected from the straight-chain alkanes with 18 to 22 carbon atoms, when the phase transition energy storage material transitions from the solid state to the liquid state by absorbing the heat from the chip 102, a variation in a density of the phase transition energy storage material is less than or equal to 3%, and the fluidity of the phase transition energy storage material is not enhanced significantly, such that the phase transition energy storage material is not prone to flow away during usage due to repeated state variations, which is may extend service life of the chip package structure 100. Meanwhile, when the phase transition energy storage material is selected from the straight-chain alkanes with 18 to 22 carbon atoms, the phase transition temperature of the phase transition energy storage material is 28° C. to 44° C., and the energy storage value of the phase transition energy storage material is 230 KJ/Kg to 250 KJ/Kg, which may absorb the heat generated by the chip 102 timely prior to overheating of the chip 102. Moreover, the phase transition energy storage material remains at its melting point for an increased time when the transition from the solid state to the liquid state occurs, which may improve the heat dissipation capability of the chip package structure 100 for the chip 102. Referring to FIG. 7, when n-docosane is used as the phase transition energy storage material, the heating-up of the chip package structure 100 is delayed effectively, and the increased temperature of the chip package structure 100 is reduced in the same time.

In some examples of the present application, the energy storage material layer 103 further comprises a heat conduction material that is dispersed in the phase transition energy storage material. This may increase transfer of the heat from the chip 102 to the phase transition energy storage material, such that the energy storage material layer 103 absorbs the heat generated by the chip 102 during working, which may improve the heat dissipation capability of the chip package structure 100 for the chip 102.

In some examples of the present application, the heat conduction material is selected from metal oxide powder or silicon dioxide powder. The metal oxide powder may be powder of a metal oxide with good heat conductivity, such as aluminum oxide, etc.

In some examples of the present application, a mass fraction of the heat conduction material in the energy storage material layer 103 is greater than or equal to 3%, and the mass fraction of the heat conduction material in the energy storage material layer 103 is less than or equal to 8%. For example, the mass fraction of the heat conduction material in the energy storage material layer 103 may be 4%, 5%, 6%, 7%, etc.

Referring to FIG. 5, in some examples of the present application, the material of the first portion 1041 covering the chip 102 is the same as the material of the second portion 1042 covering the energy storage material layer 103.

The first portion 1041 and the second portion 1042 are disposed integrally, and the material of the package layer 104 is a plastic package material, for example, the material of the package layer 104 may comprise an epoxy resin material. The chip 102 and the energy storage material layer 103 may be jointly cladded within the plastic package material. Referring to FIG. 7, when the chip 102 and the energy storage material layer 103 are jointly cladded within the plastic package material, the heating-up of the chip package structure 100 is delayed, and the increased temperature of the chip package structure 100 is reduced.

Referring to FIG. 5, in some examples of the present application, when the material of the first portion 1041 covering the chip 102 is the same as the material of the second portion 1042 covering the energy storage material layer 103, the chip package structure 100 further comprises a first heat conduction support frame 105 connected between the chip 102 and the energy storage material layer 103, which may transfer the heat from the chip 102 to the energy storage material layer 103, such that the energy storage material layer 103 absorbs the heat generated by the chip 102 during working.

In some examples of the present application, the first heat conduction support frame 105 comprises at least a first connection sub-portion, wherein an end of the first connection sub-portion close to the chip 102 is in direct contact with the chip 102; or the end of the first connection sub-portion close to the chip 102 is disposed as being adhered to the chip 102.

When the first heat conduction support frame 105 has a plurality of first connection sub-portions, the plurality of first connection sub-portions are arranged spaced apart along a direction parallel to the substrate 101, and extending directions of the plurality of first connection sub-portions may be parallel to each other. For example, the first heat conduction support frame 105 may have two first connection sub-portions (as shown by 105a and 105b in FIG. 5). The two first connection sub-portions are located on a side of the chip 102 opposite the substrate 101 and are arranged spaced apart, and the extending directions of the two first connection sub-portions are parallel to each other.

An end of each of the first connection sub-portions close to the energy storage material layer 103 is in direct contact with the energy storage material layer 103; or the end of each of the first connection sub-portions close to the energy storage material layer 103 is disposed as being adhered to the energy storage material layer 103; or in a direction from the chip 102 to the energy storage material layer 103. The first heat conduction support frame 105 further comprises a second connection sub-portion (not shown) on a side of the first connection sub-portions close to the energy storage material layer 103, the side of the first connection sub-portions close to the energy storage material layer 103 is connected with the second connection sub-portion, and the second connection sub-portion is in direct contact with the energy storage material layer 103.

Orthographic projections of the first connection sub-portions on the substrate 101 are within an orthographic projection of the second connection sub-portion on the substrate 101, e.g., the area of the orthographic projection of the second connection sub-portion on the substrate 101 is greater than a sum of areas of the orthographic projections of the first connection sub-portions on the substrate 101. By disposing the second connection sub-portion, the contact area between the first heat conduction support frame 105 and the energy storage material layer 103 is increased, which enables the first heat conduction support frame 105 to transfer the heat generated by the chip 102 to the energy storage material layer 103, thereby improving the heat dissipation capability of the chip package structure 100 for the chip 102.

In some examples of the present application, in the direction from the chip 102 to the energy storage material layer 103, a side of the energy storage material layer 103 close to the chip 102 is entirely in contact with the second connection sub-portion, which provides full contact between the energy storage material layer 103 and the first heat conduction support frame 105. The first heat conduction support frame 105 transfers the heat generated by the chip 102 to the energy storage material layer 103, thereby improving the heat dissipation capability of the chip package structure 100 for the chip 102.

In some examples of the present application, the first connection sub-portions and the second connection sub-portion may be disposed integrally.

In some examples of the present application, the material of the first heat conduction support frame 105 is selected from a metal, a metal oxide or silicon dioxide. The metal may be selected from metals such as copper, aluminum and the like, or an alloy including the above-mentioned metals. The metal oxide may be selected from metal oxides with a heat conduction property, such as aluminum oxide, etc.

Referring to FIG. 6, in some examples of the present application, the material of the first portion 1041 covering the chip 102 is different from the material of the second portion 1042 covering the energy storage material layer 103.

In some examples of the present application, when the material of the first portion 1041 covering the chip 102 is different from the material of the second portion 1042 covering the energy storage material layer 103, the first portion 1041 covering the chip 102 comprises a groove 1041a that is located on a side of the first portion 1041 covering the chip 102 opposite the substrate 101, and the energy storage material layer 103 is filled within the groove 1041a.

The second portion 1042 covering the energy storage material layer 103 comprises a second heat conduction support frame 106 that comprises a support sub-portion 106a and a cover plate sub-portion 106b. The support sub-portion 106a extends into the energy storage material layer 103. The cover plate sub-portion 106b is connected to an end of the support sub-portion 106a opposite the chip 102 and covers at least part of the energy storage material layer 103.

In some examples of the present application, an end of the support sub-portion 106a close to the chip 102 is in contact with the bottom of the groove 1041a, and a side of the cover plate sub-portion 106b opposite the support sub-portion 106a is coplanar with a side of the package layer 104 outside the groove 1041a opposite the chip 102.

In some examples of the present application, the second heat conduction support frame 106 comprises one or more support sub-portions 106a. When the second heat conduction support frame 106 comprises a plurality of support sub-portions 106a, the plurality of support sub-portions 106a are arranged spaced apart in a direction parallel to the substrate 101, and extending directions of the plurality of support sub-portions 106a may be parallel to each other. In an example, the second heat conduction support frame 106 comprises the plurality of support sub-portions 106a, which increases the contact area between the second heat conduction support frame 106 and the energy storage material layer 103. Ends of the support sub-portions 106a close to the chip 102 are in contact with the bottom of the groove 1041a. After the heat generated by the chip 102 is transferred to the groove 1041a, the heat from the chip 102 is transferred to the energy storage material layer 103 through the support sub-portions 106a in contact with the groove 1041a, thereby improving the heat dissipation capability of the chip package structure 100 for the chip 102.

In some examples of the present application, the support sub-portions 106a and the cover plate sub-portion 106b are disposed integrally.

In some examples of the present application, the material of the second heat conduction support frame 106 is selected from a metal or silicon dioxide. The metal may be selected from metals such as copper, aluminum and the like, or an alloy including the above-mentioned metals.

In some examples of the present application, the material of the first portion 1041 covering the chip 102 comprises epoxy resin, and the material of the second portion 1042 covering the energy storage material layer 103 comprises a metal. When the material of the second portion 1042 covering the energy storage material layer 103 comprises the metal, the material of the second heat conduction support frame 106 is selected from a metal, for example, may be selected from metals, such as copper, aluminum and the like, or an alloy including the above-mentioned metals.

Referring to FIG. 6, in some examples of the present application, the chip package structure 100 further comprises a sealant 107 filled between the cover plate sub-portion 106b and the sidewall of the groove 1041a. There is a gap between the cover plate sub-portion 106b and the sidewall of the groove 1041a, and the sealant 107 is filled between the cover plate sub-portion 106b and the sidewall of the groove 1041a to fill the gap, thus enhancing the effect of packaging of the chip package structure 100.

According to the chip package structure 100 provided by the present application, by disposing the energy storage material layer 103 on a side of the chip 102, the energy storage material layer 103 absorbs the heat generated by the chip 102, thereby improving the heat dissipation capability of the chip package structure 100 for the chip 102.

Examples of the present application further provide a memory comprising the chip package structure 100 of any one of the above examples.

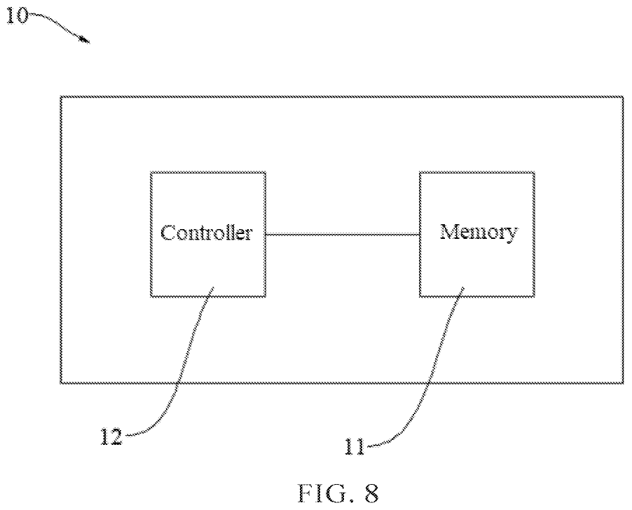

Referring to FIG. 8, examples of the present application further provide a memory system 10 comprising a controller 12 and a memory 11. The controller 12 is coupled to the memory 11 and is configured to control the memory 11 to store data, wherein the memory 11 comprises the chip package structure 100 of any one of the above examples.

The memory system 10 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memories therein. The controller 12 may be configured to control operations of the semiconductor package structures, such as reading, erasing, and programming operations.

In some examples, the controller 12 is designed for operating in a low duty-cycle environment such as Secure Digital (SD) cards, Compact Flash (CF) cards, Universal Serial Bus (USB) flash drives, or other media for use in electronic apparatuses, such as personal computers, digital cameras, mobile phones, etc.

In some examples, the controller 12 is designed for operating in high duty-cycle environment Solid-State Disks (SSDs) or Embedded Multi Media Cards (eMMCs) used as data memories for mobile apparatuses, such as smartphones, tablets, laptop computers, etc., and enterprise memory arrays.

The present application provides a chip package structure and a fabrication method thereof, a memory and a memory system. The chip package structure comprises a substrate, a chip on a side of the substrate, an energy storage material layer on a side of the chip opposite the substrate, and a package layer that comprises a first portion covering the chip and a second portion covering the energy storage material layer. According to the present application, by disposing the energy storage material layer on a side of the chip, the energy storage material layer absorbs the heat generated by the chip, thereby improving the heat dissipation capability of the chip package structure for the chip.

A chip package structure and a fabrication method thereof provided by examples of the present application are introduced above in detail. The principle and implementations of the present application are set forth herein by applying specific individual examples. The descriptions of the examples above are only used to help understand the methods and ideas of the present application. Meanwhile, those skilled in the art may make changes over the specific implementations and application scope according to the ideas of the present application. Hence, the contents of this specification should not be interpreted as limitations to the present application.

What is claimed is:

1. A fabrication method of a chip package structure, comprising:
disposing a chip on a side of a substrate;
disposing an energy storage material layer on a side of the chip opposite the substrate; and
forming a package layer on a same side of the substrate as the chip, wherein the package layer covers the chip and the energy storage material layer.

2. The fabrication method of claim 1, wherein the chip package structure further comprises a first heat conduction support frame connected between the chip and the energy storage material layer; and
before disposing the energy storage material layer on the side of the chip opposite the substrate, the fabrication method further comprises:
disposing the first heat conduction support frame on the side of the chip opposite the substrate.

3. The fabrication method of claim 2, wherein disposing the energy storage material layer on the side of the chip opposite the substrate comprises:
providing an energy storage material in liquid state; and
cooling and solidifying the energy storage material in liquid state to form the energy storage material layer on a side of the first heat conduction support frame opposite the chip.

4. The fabrication method of claim 3, wherein the energy storage material layer comprises a phase transition energy storage material and a heat conduction material; and
providing the energy storage material in liquid state comprises:
providing the phase transition energy storage material in liquid state; and
mixing the heat conduction material into the phase transition energy storage material in liquid state to form the energy storage material in liquid state.

5. The fabrication method of claim 4, wherein a mass fraction of the heat conduction material in the energy storage material layer is greater than or equal to 3%, and the mass fraction of the heat conduction material in the energy storage material layer is less than or equal to 8%.

6. A fabrication method of a chip package structure, comprising:
disposing a chip on a side of a substrate;
forming a pre-package layer on a side of the chip opposite the substrate, wherein the pre-package layer covers the chip;
forming a groove on a side of the pre-package layer opposite the substrate to form a first portion of a package layer; and
filling an energy storage material within the groove to form an energy storage material layer, wherein the energy storage material layer comprises a phase transition energy storage material.

7. The fabrication method of claim 6, wherein the package layer further comprises a second portion covering the energy storage material layer, and the second portion covering the energy storage material layer comprises a second heat conduction support frame, and wherein the second heat conduction support frame comprises a support sub-portion and a cover plate sub-portion, the support sub-portion extends into the energy storage material layer, and the cover plate sub-portion is connected to an end of the support sub-portion opposite the chip and covers at least part of the energy storage material layer.

8. The fabrication method of claim 7, wherein filling the energy storage material within the groove to form the energy storage material layer comprises:
providing an energy storage material in liquid state;
filling the energy storage material in liquid state within the groove;
disposing the second heat conduction support frame in the energy storage material in liquid state located within the groove to fully fill the groove; and
cooling and solidifying the energy storage material within the groove to form the energy storage material layer.

9. The fabrication method of claim 8, wherein the energy storage material layer comprises a phase transition energy storage material and a heat conduction material; and
providing the energy storage material in liquid state comprises:
providing the phase transition energy storage material in liquid state; and
mixing the heat conduction material into the phase transition energy storage material in liquid state to form the energy storage material in liquid state.

10. The fabrication method of claim 9, wherein a mass fraction of the heat conduction material in the energy storage material layer is greater than or equal to 3%, and the mass fraction of the heat conduction material in the energy storage material layer is less than or equal to 8%.

11. The fabrication method of claim 7, wherein filling the energy storage material within the groove to form the energy storage material layer comprises:
providing an energy storage material in solid state; and
filling the energy storage material in solid state within the groove to form the energy storage material layer.

12. The fabrication method of claim 11, wherein after the filling the energy storage material within the groove to form the energy storage material layer, the fabrication method further comprises:
providing the second heat conduction support frame; and
placing the support sub-portion of the second heat conduction support frame into the energy storage material layer to fully fill the groove.

13. The fabrication method of claim 7, wherein the chip package structure further comprises a sealant filled between the cover plate sub-portion and a sidewall of the groove; and
after filling the energy storage material within the groove to form the energy storage material layer, the fabrication method further comprises:
filling the sealant between the cover plate sub-portion and the sidewall of the groove.

14. A chip package structure, comprising:
a substrate;
a chip on a side of the substrate;
an energy storage material layer on a side of the chip opposite the substrate; and
a package layer comprising a first portion covering the chip and a second portion covering the energy storage material layer.

15. The chip package structure of claim 14, wherein a material of the first portion covering the chip is the same as a material of the second portion covering the energy storage material layer.

16. The chip package structure of claim 15, wherein the chip package structure further comprises a first heat conduction support frame connected between the chip and the energy storage material layer.

17. The chip package structure of claim 14, wherein a material of the first portion covering the chip is different from a material of the second portion covering the energy storage material layer.

18. The chip package structure of claim 17, wherein the first portion covering the chip comprises a groove that is located on a side of the first portion covering the chip opposite the substrate, and the energy storage material layer is filled within the groove; wherein the second portion covering the energy storage material layer comprises a second heat conduction support frame that comprises a support sub-portion and a cover plate sub-portion, wherein the support sub-portion extends into the energy storage material layer, and the cover plate sub-portion is connected to an end of the support sub-portion opposite the chip and covers at least part of the energy storage material layer.

19. The chip package structure of claim 18, wherein the material of the first portion covering the chip comprises epoxy resin, and the material of the second portion covering the energy storage material layer comprises a metal.

20. The chip package structure of claim 18, wherein the chip package structure further comprises a sealant filled between the cover plate sub-portion and a sidewall of the groove.
